(19) United States
(12) Patent Application Publication
(10) Pub. No.: US 2025/0081436 A1
(43) Pub. Date: Mar. 6, 2025

(54) SEMICONDUCTOR DEVICE

(71) Applicant: Kioxia Corporation, Tokyo (JP)

(72) Inventors: Kotaro NODA, Yokkaichi Mie (JP); Akio KANEKO, Kamakura Kanagawa (JP); Masayuki MURASE, Yokkaichi Mie (JP); Akifumi GAWASE, Kuwana Mie (JP); Kazuhiro KATONO, Mie Mie (JP)

(21) Appl. No.: 18/823,386

(22) Filed: Sep. 3, 2024

(30) Foreign Application Priority Data
Sep. 5, 2023 (JP) 2023-143721

(51) Int. Cl. H10B 12/00

(52) U.S. Cl. CPC H10B 12/33; H10B 12/05

(57) ABSTRACT

According to one embodiment, a semiconductor device includes a first electrode with a first electrode portion and a second electrode portion on the first electrode portion. An oxide semiconductor layer is on the second electrode portion. A gate electrode layer surrounds part of an outer side wall of the oxide semiconductor layer. A gate insulating layer surrounds the outer side wall of the oxide semiconductor layer such that the gate insulating layer is between the oxide semiconductor layer and the gate electrode layer. A distance between the second electrode portion and the gate electrode layer is less than a distance between the first electrode portion and the gate electrode layer.

### CROSS-REFERENCE TO RELATED APPLICATIONS

This application is based upon and claims the benefit of priority from Japanese Patent Application No. 2023-143721, filed Sep. 5, 2023, the entire contents of which are incorporated herein by reference.

### FIELD

Embodiments described herein relate generally to a semiconductor device that includes an oxide semiconductor layer.

### BACKGROUND

A semiconductor device that uses a transistor including an oxide semiconductor layer is known. In the transistor, a channel can be formed in the oxide semiconductor layer.

### BRIEF DESCRIPTION OF THE DRAWINGS

FIG. 1 is a top view showing a schematic configuration of a semiconductor device according to a first embodiment.

FIG. 2 is a cross-sectional view taken along line A-A of FIG. 1.

FIG. 3 depicts a structure in which a capacitor and a side surface of a first electrode portion are surrounded by an insulating layer.

FIG. 4 depicts an example of a structure where a capacitor and a side surface of a first electrode portion are surrounded by an insulating layer, and a side surface and a bottom surface of the first electrode portion are surrounded by a barrier metal layer.

FIG. 5 depicts an example of a structure of an upper electrode.

FIG. 6 depicts a distance between a first electrode portion and a gate electrode layer, and a distance between a second electrode portion and the gate electrode layer.

FIG. 7 depicts aspects of a process of manufacturing a semiconductor device according to a first embodiment.

FIG. 8 depicts aspects of a process of manufacturing a semiconductor device according to a first embodiment.

FIG. 9 depicts aspects of a process of manufacturing a semiconductor device according to a first embodiment.

FIG. 10 is an equivalent circuit diagram for a part of a memory cell array of a DRAM.

FIG. 11 is a cross-sectional view showing a semiconductor device according to a second embodiment.

FIG. 12 is a cross-sectional view showing a semiconductor device according to a third embodiment.

FIG. 13 is a cross-sectional view showing a semiconductor device according to a fourth embodiment.

FIG. 14 depicts aspects of a process of manufacturing a semiconductor device according to a fourth embodiment.

FIG. 15 depicts aspects of a process of manufacturing a semiconductor device according to a fourth embodiment.

FIG. 16 is a cross-sectional view showing a semiconductor device according to a fifth embodiment.

FIG. 17 depicts aspects of a process of manufacturing a semiconductor device according to a fifth embodiment.

FIG. 18 depicts aspects of a process of manufacturing a semiconductor device according to a fifth embodiment.

FIG. 19 depicts aspects of a process of manufacturing the semiconductor device according to a fifth embodiment.

FIG. 20 is a cross-sectional view showing a semiconductor device according to a modified example of a fifth embodiment.

FIG. 21 depicts aspects of a process of manufacturing a semiconductor device according to a modified example of a fifth embodiment.

FIG. 22 is a cross-sectional view showing a semiconductor device according to a sixth embodiment.

FIG. 23 depicts aspects of a process of manufacturing a semiconductor device according to a sixth embodiment.

FIG. 24 is a cross-sectional view showing a semiconductor device according to a seventh embodiment.

FIG. 25 is a cross-sectional view showing a semiconductor device according to a modified example of a seventh embodiment.

FIG. 26 depicts aspects of a process of manufacturing a semiconductor device according to a modified example of a seventh embodiment.

FIG. 27 is a cross-sectional view showing a semiconductor device according to an eighth embodiment.

### DETAILED DESCRIPTION

An embodiment of the present disclosure describes a semiconductor device that includes an oxide semiconductor layer that can facilitate improved electric characteristics.

In general, according to one embodiment, a semiconductor device has a first electrode with a first electrode portion and a second electrode portion on the first electrode portion. An oxide semiconductor layer is on the second portion. A gate electrode layer surrounds part of an outer side wall of the oxide semiconductor layer. A gate insulating layer surrounds the outer side wall of the oxide semiconductor layer. The gate insulating layer is between the oxide semiconductor layer and the gate electrode layer. A distance between the second electrode portion and the gate electrode layer is less than a distance between the first electrode portion and the gate electrode layer.

Hereinafter, certain example embodiments are described with reference to the drawings. Note that the drawings are schematic or conceptual. The dimensions, proportions and the like in the drawings are not necessarily identical to those of actual examples. In the drawings, the same symbols are assigned to the same or corresponding portions. Redundant description may be omitted. For the sake of representational simplification, aspects, components, symbols, or labels may be omitted from certain drawings.

### First Embodiment

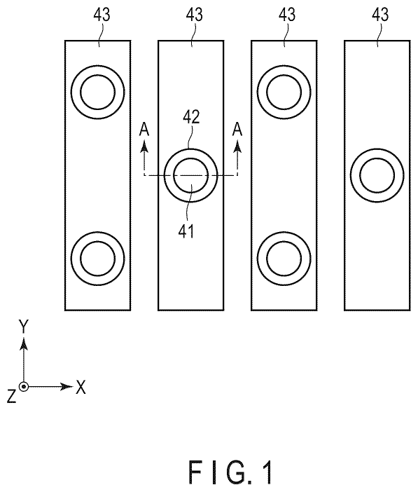

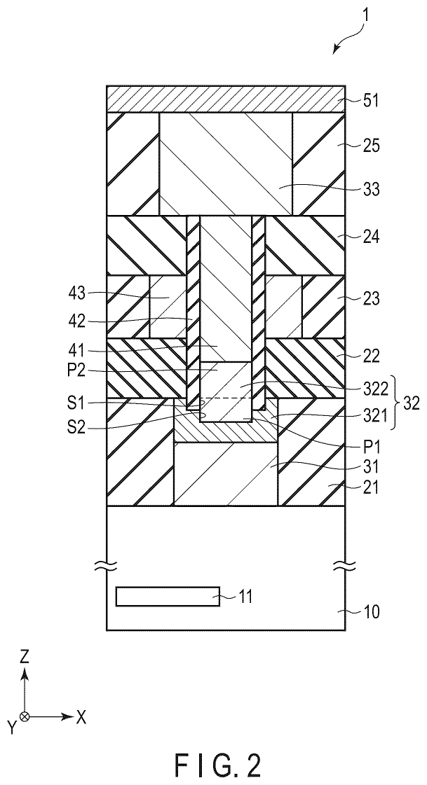

FIG. 1 is a top view showing a semiconductor device 1 according to a first embodiment. FIG. 2 is a cross-sectional view taken along line A-A of FIG. 1.

The semiconductor device 1 includes a substrate 10, insulating layers 21 to 25, a capacitor 31, a lower electrode 32 (with portions 321 and 322), an upper electrode 33, an oxide semiconductor layer 41, a gate insulating layer 42, a gate electrode layer 43, and a bit line 51.

The substrate 10 can be a semiconductor substrate, such as a silicon substrate. The thickness direction of the substrate 10 is the direction of the Z-axis. The semiconductor substrate is provided with a CMOS (complementary metal-oxide semiconductor) circuit 11.

An insulating layer 21 is provided on the substrate 10. The insulating layer 21 is, for example, a silicon nitride layer. The silicon nitride layer can be formed using a plasma CVD method.

The capacitor 31 is provided on the substrate 10. The lower electrode 32 is provided on the capacitor 31. The capacitor 31 includes therein, for example, a lower capacitor electrode, a dielectric layer, and an upper capacitor electrode. The dielectric layer is provided between the lower capacitor electrode and the upper capacitor electrode.

The lower capacitor electrode is electrically connected to the CMOS circuit 11. The upper capacitor electrode is electrically connected to the lower electrode 32. For example, an insulating layer can be provided on the capacitor 31. Through a through-hole formed in this insulating layer, the upper capacitor electrode of capacitor 31 is electrically connected to the lower electrode 32.

The lower electrode 32 includes a first electrode portion 321 and a second electrode portion 322. The second electrode portion 322 is provided in or on part of the first electrode portion 321. In this embodiment, the second electrode portion 322 is on or extends into an upper part of the first electrode portion 321. The side surface (outer side wall) of the capacitor 31 and the side surface (outer side wall) of the first electrode portion 321 are surrounded by the insulating layer 21.

The second electrode portion 322 includes a first portion P1 and a second portion P2. The first portion P1 is inside of the first electrode portion 321, and the second portion P2 is outside of (beyond) the first electrode portion 321. In other words, the first portion P1 is a part inserted into the upper part of the first electrode portion 321, and the second portion P2 is a part protruding from the first electrode portion 321 in the arrow direction of the Z-axis (the positive direction of the Z-axis). The upper surface of the second portion P2 is higher than the upper surface of the first electrode portion 321 outside of the gate insulating layer 42.

The shape of the second electrode portion 322 is a cylindrical shape extending in the Z-axis direction. The shape of the first electrode portion 321 is a cylindrical shape extending in the Z-axis direction except that into the upper part of this portion, the first portion P1 is inserted.

The diameter of the second electrode portion 322 is smaller than the diameter of the first electrode portion 321. The second electrode portion 322 is positioned inside of the upper surface of the first electrode portion 321. Note that the shapes of the first electrode portion 321 and the second electrode portion 322 may be other than cylindrical shapes.

The side surface of the first portion P1 includes a first side surface S1 surrounded by the first electrode portion 321 and a second side surface S2 surrounded by the gate insulating layer 42. The side surface of the second portion P2 is surrounded by the gate insulating layer 42.

The material of the first electrode portion 321 and the material of the second electrode portion 322 are, for example, ITO (indium tin oxide). Even in a case in which the material of the first electrode portion 321 and the material of the second electrode portion 322 are the same, the interface (boundary) between the first electrode portion 321 and the second electrode portion 322 may be detected by, for example, physical analysis using a transmission electron microscope (TEM), physical analysis using energy dispersive X-ray spectrometry (EDS) or the like. The material of the first electrode portion 321 may be different from the material of the second electrode portion 322 in some examples.

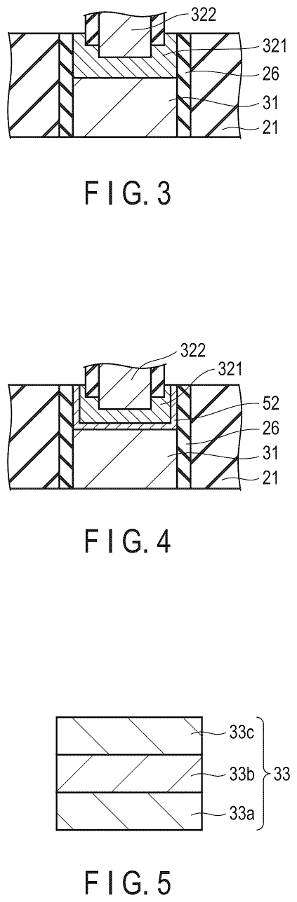

Note that a structure shown in FIG. 3 or FIG. 4 may be applied to the semiconductor device 1 in the embodiment shown in FIG. 2.

FIG. 3 shows an example of a structure where the capacitor 31 and the side surface of the first electrode portion 321 are surrounded by an insulating layer 26. For example, the insulating layer 21 is a silicon nitride layer, and the insulating layer 26 is a silicon oxide layer.

FIG. 4 shows an example of a structure where the capacitor 31 and the side surface of the first electrode portion 321 are surrounded by the insulating layer 26, and the side surface and the bottom surface of the first electrode portion 321 are surrounded by a barrier metal layer 52. The barrier metal layer 52 is, for example, a titanium nitride layer.

Referring to FIG. 2, the oxide semiconductor layer 41 is provided on the second electrode portion 322 (more specifically, the second portion P2). In this first embodiment, the shape of the oxide semiconductor layer 41 is a column or cylindrical shape extending in the Z-axis direction.

The lower surface of the oxide semiconductor layer 41 is in contact with the upper surface of the second portion P2. In this first embodiment, the shape of the lower surface of the oxide semiconductor layer 41 is flat, and the shape of the upper surface of the second portion P2 is flat. Thus, the interface between the lower surface of the oxide semiconductor layer 41 and the upper surface of the second portion P2 is flat.

The oxide semiconductor layer 41 comprises, for example, indium, gallium, zinc, and oxygen. A material that comprises indium, gallium, zinc, and oxygen is called IGZO (indium gallium zinc oxide) and can be used. The oxide semiconductor layer 41 contains an n-type dopant or a p-type dopant.

The side surface of the oxide semiconductor layer 41 is surrounded by the gate insulating layer 42. The gate insulating layer 42 comprises, for example, silicon oxide. Part of the side surface of the oxide semiconductor layer 41 is surrounded by the gate electrode layer 43 via the gate insulating layer 42. The gate electrode layer 43 is, for example, a tungsten (W) layer. The gate electrode layer 43 has a shape extending in the Y-axis direction. A plurality of the gate electrode layers 43 are arranged in the X-axis direction.

The oxide semiconductor layer 41, the gate insulating layer 42, and the gate electrode layer 43 constitute a vertical transistor. The channel of the vertical transistor is formed in the oxide semiconductor layer 41. The direction of the channel is the direction (Z-axis direction) perpendicular to the upper surface of the substrate 10. The vertical transistor is also called an SGT (Surrounding Gate Transistor).

The vertical transistor using the oxide semiconductor layer 41 is a junctionless transistor that requires no pn junction. In a junctionless transistor, the conduction types of the source region, the drain region, and the channel region are the same.

The side surface of the gate insulating layer 42 surrounding the side surface of the second portion P2 is surrounded by an insulating layer 22. Furthermore, the side surface of the gate insulating layer 42 surrounding the side surface of the lower part of the oxide semiconductor layer 41 is also surrounded by the insulating layer 22.

The side surface of the gate electrode layer 43 is surrounded by an insulating layer 23. The side surface of the gate insulating layer 42 surrounding the side surface of the upper part of the oxide semiconductor layer 41 is surrounded by an insulating layer 24. The insulating layers 22 to 24 are, for example, silicon oxide layers.

The upper electrode 33 is provided on the upper surface of the oxide semiconductor layer 41. In this embodiment, the upper electrode 33 is provided on the upper surface of the gate insulating layer 42 and also on the upper surface of the insulating layer 24 therearound. The side surface of the upper electrode 33 is surrounded by an insulating layer 25. The insulating layer 25 is, for example, a silicon oxide layer.

FIG. 5 shows an example of the structure of the upper electrode 33. The upper electrode 33 includes a first metal layer 33a, a barrier metal layer 33b, and a second metal layer 33c. The barrier metal layer 33b is provided between the first metal layer 33a and the second metal layer 33c. For example, the first metal layer 33a is an ITO layer, the barrier metal layer 33b is a titanium nitride layer, and the second metal layer 33c is a W layer.

The bit line 51 is provided on the upper electrode 33. The upper electrode 33 is electrically connected to the bit line 51.

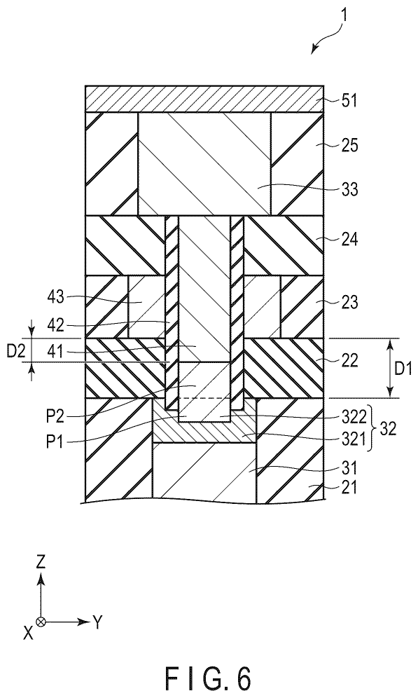

FIG. 6 shows a distance D1 between the first electrode portion 321 and the gate electrode layer 43, and a second distance D2 between the second electrode portion 322 and the gate electrode layer 43.

More specifically, the first distance D1 is the distance between the upper surface of the first electrode portion 321 outside of the gate insulating layer 42, and the lower surface of the gate electrode layer 43. Meanwhile, more specifically, the second distance D2 is the distance between the upper surface of the second portion P2 of the second electrode portion 322, and the lower surface of the gate electrode layer 43.

The second portion P2 is the portion protruding from the first electrode portion 321. Accordingly, the second distance D2 is smaller than the first distance D1 (D1>D2). The upper surface of the second portion P2 is lower than the lower surface of the gate electrode layer 43.

As described above, the lower electrode 32 includes the first electrode portion 321 and the second electrode portion 322, and the second electrode portion 322 includes the second portion P2 protruding from the first electrode portion 321.

In the case with the second portion P2 as in this embodiment, the distance between the lower electrode 32 and the gate electrode layer 43 serves as the second distance D2. In a case without the second portion P2, the distance between the lower electrode 32 and the gate electrode layer 43 serves as the first distance D1.

According to this embodiment, the distance between the lower electrode 32 and the gate electrode layer 43 can be smaller by the distance otherwise caused by the presence of the second portion P2. Consequently, the electric field between the lower electrode 32 and the gate electrode layer 43 can be large.

As the electric field between the lower electrode 32 and the gate electrode layer 43 becomes large, current flowing through the channel formed in the oxide semiconductor layer 41 becomes large, and the variation in on-state current becomes small. Consequently, this embodiment can provide the semiconductor device 1 that includes the oxide semiconductor layer 41 and can facilitate improvement in electric characteristics.

As described above, according to this embodiment, by adopting the lower electrode 32 that includes the first electrode portion 321 and the second electrode portion 322, the electric field between the lower electrode 32 and the gate electrode layer 43 can be large, which can provide the semiconductor device 1 that includes the oxide semiconductor layer 41 and can facilitate improvement in electric characteristics.

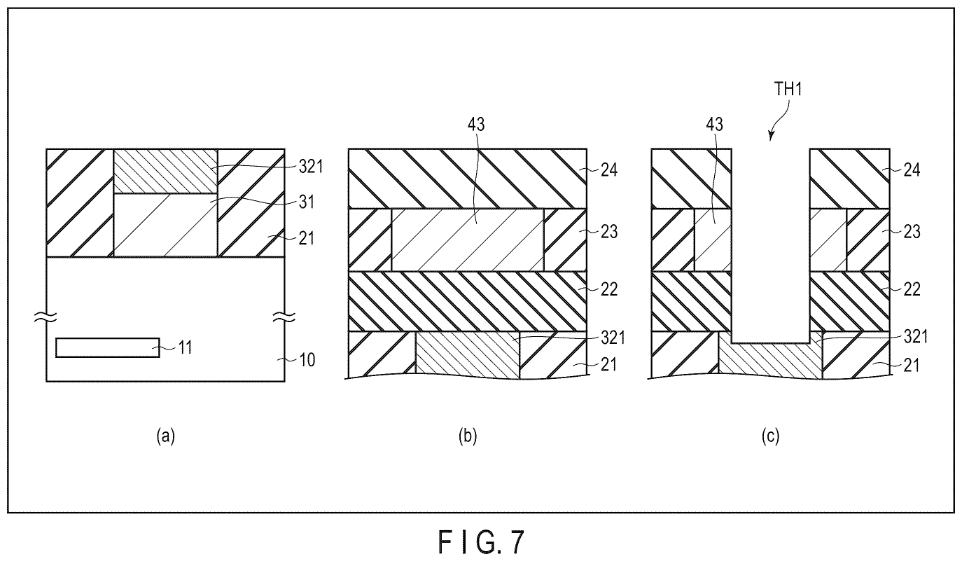

Next, an example of a method of manufacturing the semiconductor device of this embodiment is described. FIGS. 7 to 9 show aspects of a process of manufacturing the semiconductor device of the present embodiment. The cross-sectional views of FIGS. 7 to 9 correspond to cross-sectional views taken along line A-A of FIG. 1.

First, as shown in FIG. 7, part (a), the substrate 10, the insulating layer 21, the capacitor 31, and the first electrode portion 321 are formed. The substrate 10 can be a semiconductor substrate, such as a silicon substrate. The CMOS circuit 11 is formed on/in the semiconductor substrate and can be considered a sub-part thereof in some contexts. An insulating layer may be formed over the semiconductor substrate and the CMOS circuit 11.

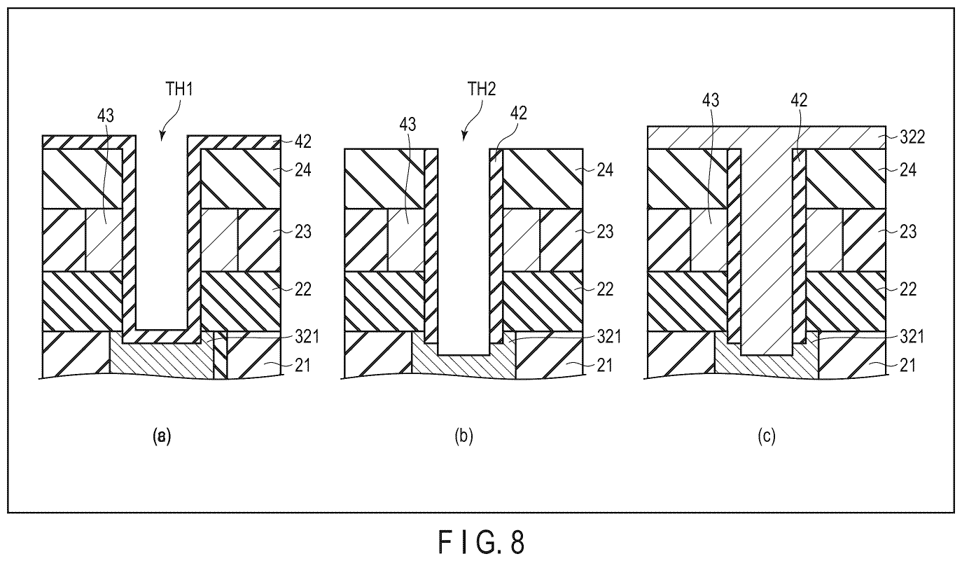

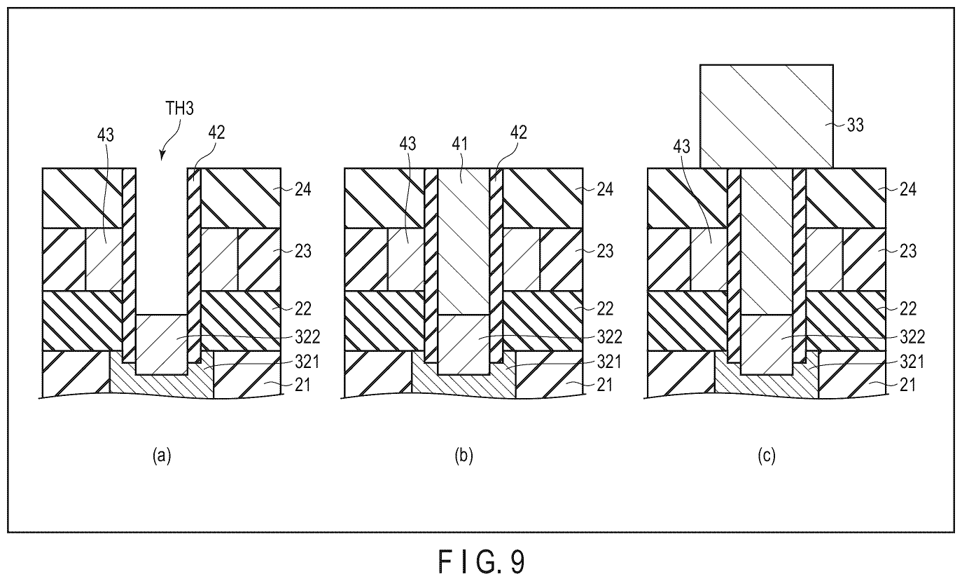

Note that in FIG. 7, part (b), FIG. 8, parts (a)-(c), and FIG. 9, part (a)-(c), the substrate 10 and the capacitor 31 are omitted for sake of simplicity. The lower portions of the first electrode portion 321 and the insulating layer 21 are indicated using break lines (wavy lines), for the sake of simplicity.

Next, as shown in FIG. 7, part (b), the insulating layer 22 is formed on the insulating layer 21 and the first electrode portion 321. Next, the gate electrode layer 43 is formed on the insulating layer 22. Next, the insulating layer 23 that covers the gate electrode layer 43 is formed on the insulating layer 22. Subsequently, the insulating layer 23 and the gate electrode layer 43 are flattened using CMP (chemical mechanical polishing). Next, the insulating layer 24 is formed on the gate electrode layer 43 and the insulating layer 23. The insulating layer 22, the insulating layer 23, and the insulating layer 24 are silicon oxide films and may be formed using a plasma CVD process using DTEOS (densified tetra ethyl ortho silicate).

Next, using a photolithography process and an etching process, the insulating layer 24, the gate electrode layer 43, the insulating layer 22, and the first electrode portion 321 are processed, and a through-hole TH1 is formed as shown in FIG. 7, part (c). The through-hole TH1 penetrates through the insulating layer 24, the gate electrode layer 43, and the insulating layer 22, and reaches a depth in the middle of the first electrode portion 321.

Next, as shown in FIG. 8, part (a), the gate insulating layer 42 is formed inside and outside of the through-hole TH1. The inside of the through-hole TH1 includes the side surface of the insulating layer 24, the side surface of the gate electrode layer 43, the side surface of the insulating layer 22, the side surface of the first electrode portion 321, and the upper surface of the first electrode portion 321. The outside of the through-hole TH1 is the upper surface of the insulating layer 24.

Next, the gate insulating layer 42 on the upper surface of the insulating layer 24, and the gate insulating layer 42 on the upper surface of the first electrode portion 321 are removed. Furthermore, as shown in FIG. 8, part (b), the first electrode portion 321 exposed by removing the gate insulating layer 42 is now etched. As a result, a through-hole TH2 that is deeper than the through-hole TH1 is formed. The removal of the gate insulating layer 42, and the etching of the first electrode portion 321 are performed using, for example, an RIE (reactive ion etching) process.

Next, as shown in FIG. 8, part (c), the second electrode portion 322 is formed over the entire surface so as to fill the through-hole TH2. The second electrode portion 322 is formed using, for example, an ALD (atomic layer deposition) process. At this stage, the second electrode portion 322 does not yet have its intended, predetermined final shape.

Next, as shown in FIG. 9, part (a), the second electrode portion 322 is recessed so that the second electrode portion 322 can reach its predetermined, intended shape (final shape). The recessing is performed using, for example, a solution containing aqua regia or NC. As a result of the recessing, a through-hole TH3 is formed on the second electrode portion 322.

The upper surface of the second electrode portion 322 after the recessing is lower than the lower surface of the gate electrode layer 43. The upper surface of the second electrode portion 322 after the recessing is higher than the upper surface of the first electrode portion 321 outside of the gate insulating layer 42.

Subsequently, steps, such as of filling the through-hole TH3 with the oxide semiconductor layer 41 (FIG. 9, part (b)), and forming the upper electrode 33 that is connected to the oxide semiconductor layer 41 (FIG. 9, part (c)), are performed, thus obtaining the semiconductor device 1 shown in FIG. 2.

The semiconductor device 1 can be, for example, a DRAM (Dynamic Random Access Memory). In the case of a DRAM, the vertical transistor can be part of a memory cell of a memory cell array, and the CMOS circuit 11 can be a CMOS circuit in a peripheral circuit.

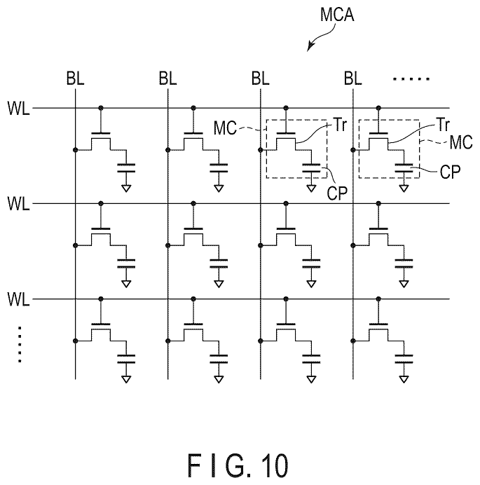

FIG. 10 shows an equivalent circuit diagram of part of a memory cell array MCA of a DRAM. The memory cell array MCA includes a plurality of memory cells MC, a plurality of word lines WL, and a plurality of bit lines BL.

The plurality of memory cells MC are arranged in a matrix manner. Each memory cell MC includes a vertical transistor Tr and a capacitor CP. Gates (gate electrode layer) of the plurality of vertical transistors Tr are connected to respective word lines WL. Drains (or sources) of the plurality of vertical transistors Tr are connected to the respective bit lines BL. One electrode of the capacitor CP is connected to, for example, a source (or a drain) of the vertical transistor Tr. The other electrode of the capacitor CP is connected to a power source line that supplies a predetermined potential (voltage).

Note that the semiconductor device 1 of this embodiment is not limited to a DRAM.

### Second Embodiment

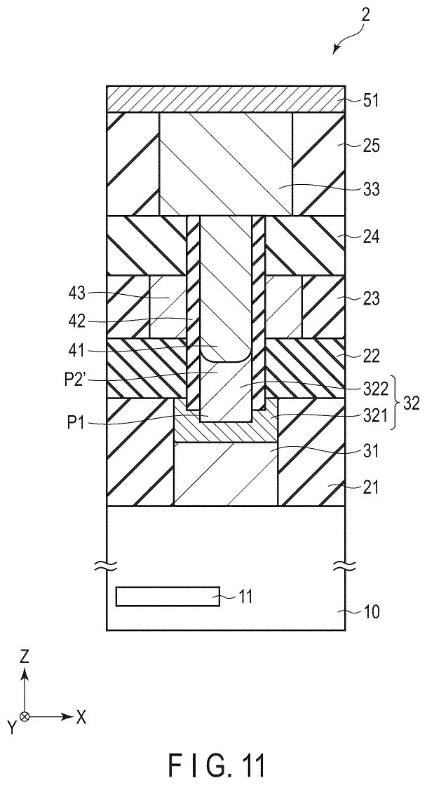

FIG. 11 is a cross-sectional view showing a semiconductor device 2 according to a second embodiment. The cross-sectional view of FIG. 11 corresponds to the view taken along line A-A of FIG. 1.

The semiconductor device 2 according to this second embodiment is different from the semiconductor device 1 according to the first embodiment in that the shape of the upper surface of the second electrode portion 322 is concave. More specifically, the shape of the upper surface of a second portion P2′ of the second electrode portion 322 at the interface between the second portion P2′ of the second electrode portion 322 and the oxide semiconductor layer 41 is concave. The second portion P2′ is a portion corresponding to the second portion P2 described in the first embodiment.

The shape of the lower surface of the oxide semiconductor layer 41 is convex. The upper surface of the second portion P2′ of the second electrode portion 322 is in contact with the lower surface of the oxide semiconductor layer 41.

Also in this second embodiment, similar to the first embodiment, the second distance is smaller than the first distance. The second distance becomes smaller toward the center of the second portion P2′ from the gate insulating layer 42.

According to this second embodiment, the electric field between the lower electrode 32 and the gate electrode layer 43 is larger than that in the case without the second portion P2′. As a result, the current flowing through the channel formed in the oxide semiconductor layer 41 can be large, which can facilitate improvement of electric characteristics.

### Third Embodiment

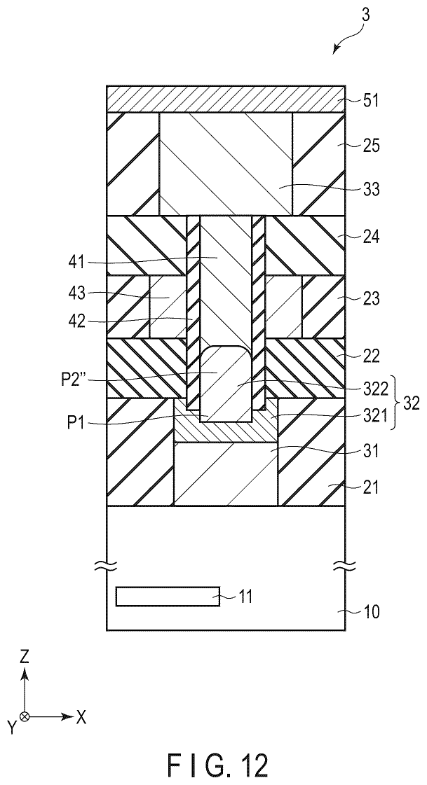

FIG. 12 is a cross-sectional view showing a semiconductor device 3 according to a third embodiment. The cross-sectional view of FIG. 12 corresponds to the view taken along line A-A of FIG. 1.

The semiconductor device 3 according to this third embodiment is different from the semiconductor device 1 according to the first embodiment in that the shape of the upper surface of the second electrode portion 322 is convex. More specifically, the shape of the upper surface of a second portion P2″ of the second electrode portion 322 at the interface between the second portion P2″ of the second electrode portion 322 and the oxide semiconductor layer 41 is convex. The second portion P2″ is a portion corresponding to the second portion P2 described in the first embodiment.

The shape of the lower surface of the oxide semiconductor layer 41 is concave. The upper surface of the second portion P2″ of the second electrode portion 322 is in contact with the lower surface of the oxide semiconductor layer 41.

Also in this third embodiment, similar to the first embodiment, the second distance is smaller than the first distance. The second distance becomes larger toward the center of the second portion P2″ from the gate insulating layer 42.

According to this third embodiment, the electric field between the lower electrode 32 and the gate electrode layer 43 is larger than that in the case without the second portion P2″. As a result, the current flowing through the channel formed in the oxide semiconductor layer 41 can be large, which can facilitate improvement of electric characteristics.

### Fourth Embodiment

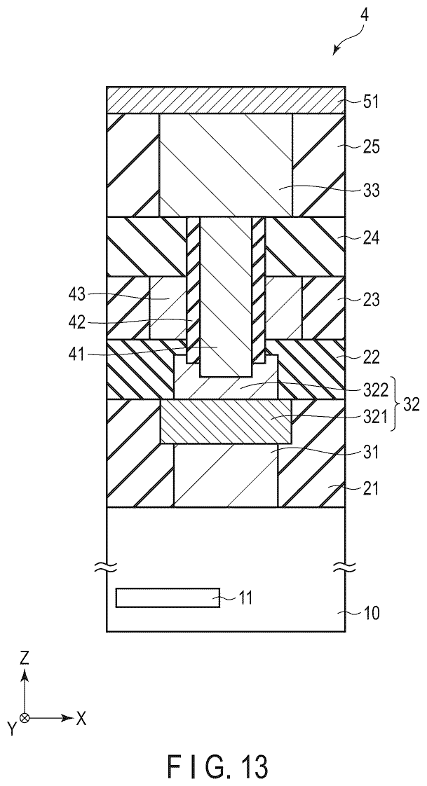

FIG. 13 is a cross-sectional view showing a semiconductor device 3 according to a fourth embodiment. The cross-sectional view of FIG. 13 corresponds to the view taken along line A-A of FIG. 1.

In the first to third embodiments, the lower part of the second electrode portion 322 is surrounded by the first electrode portion 321. However, in this fourth embodiment, the lower part of the second electrode portion 322 is not surrounded by the first electrode portion 321, and the entire second electrode portion 322 is provided on the upper surface of the first electrode portion 321. In other words, the second electrode portion 322 in each of the first to third embodiments is made up of two portions (a first portion and a second portion) but the second electrode portion 322 in this fourth embodiment is made up of a single portion corresponding to the second portion.

Also in this fourth embodiment, similar to the first embodiment, the second distance is smaller than the first distance. According to this fourth embodiment, the electric field between the lower electrode 32 and the gate electrode layer 43 is larger than that in the case without the second electrode portion 322. As a result, the current flowing through the channel formed in the oxide semiconductor layer 41 can be large, which can facilitate improvement of electric characteristics.

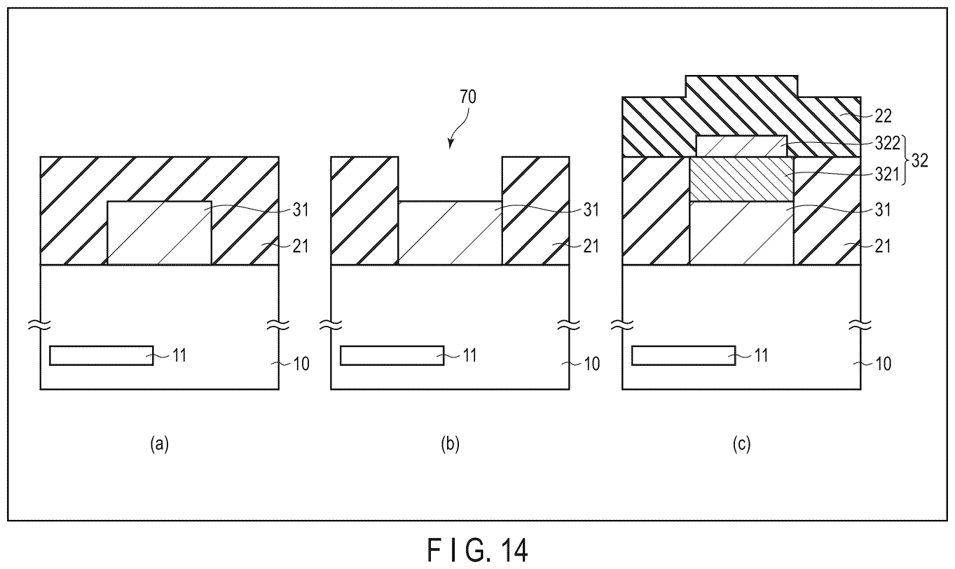

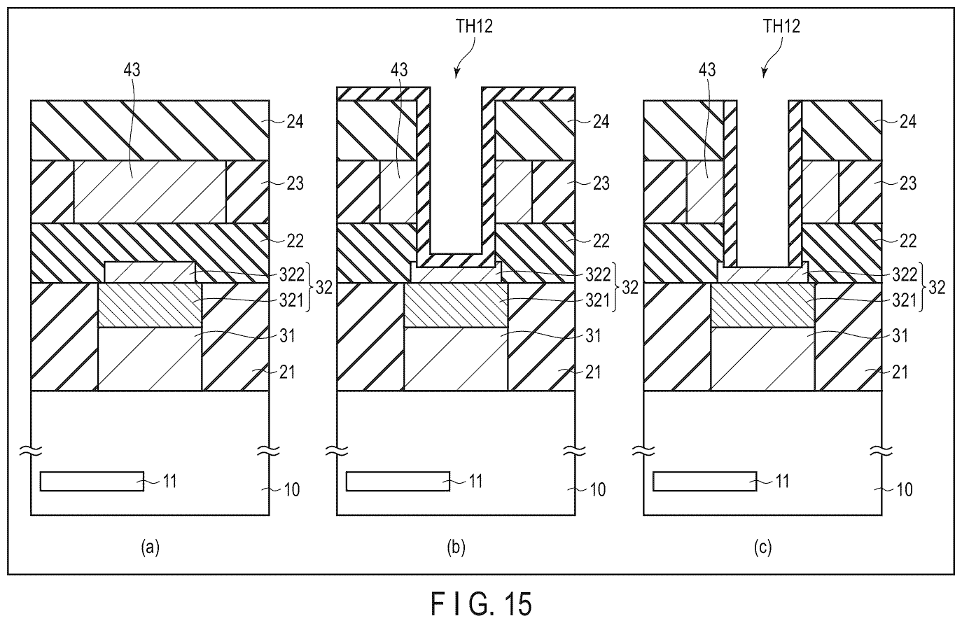

Next, an example of a method of manufacturing the semiconductor device of this fourth embodiment is described. FIGS. 14 and 15 depict aspects of a process of manufacturing the semiconductor device of this fourth embodiment.

First, as shown in FIG. 14, part (a), the capacitor 31 is formed on the substrate 10. Next, an insulating layer that is to become the insulating layer 21 is formed on the substrate 10 and the capacitor 31 so as to cover the capacitor 31, and subsequently, the insulating layer is flattened (planarized) by a CMP process, thus forming the insulating layer 21.

Next, as shown in FIG. 14, part (b), using a photolithography process and an etching process, a groove 70 for allowing the upper surface of the capacitor 31 to be exposed is formed in the insulating layer 21.

Next, as shown in FIG. 14, part (c), a conductive film (e.g., an ITO film) that is to become the first electrode portion 321 is deposited over the entire surface and fills the groove 70, and subsequently, the conductive film outside of the groove 70 is removed, and the surfaces of the conductive film and the insulating layer 21 are flattened (planarized) using a CMP process, thus forming the first electrode portion 321.

Next, the second electrode portion 322 is formed on the first electrode portion 321, and subsequently, the insulating layer 22 is formed on the first electrode portion 321, the second electrode portion 322, and the insulating layer 21.

Next, the surface of the insulating layer 22 is flattened using a CMP process, and subsequently, as shown in FIG. 15, part (a), the gate electrode layer 43, the insulating layer 23, and the insulating layer 24 are formed on the insulating layer 22.

Next, as shown in FIG. 15, part (b), using a photolithography process and an etching process, the insulating layer 24, the gate electrode layer 43, the insulating layer 22, and the second electrode portion 322 are processed, and a through-hole TH12 is formed. The through-hole TH12 penetrates through the insulating layer 24, the gate electrode layer 43, and the insulating layer 22, and reaches a depth in the middle of the second electrode portion 322. Next, the gate insulating layer 42 is conformally deposited over the entire surface so as to cover the bottom surface and the side surface of the through-hole TH12.

Next, the gate insulating layer 42 outside of the through-hole TH12, and the gate insulating layer 42 on the bottom surface of the through-hole TH12 are removed. As a result, the gate insulating layer 42 selectively covers the side wall of the through-hole TH12.

Subsequently, steps, such as forming an oxide semiconductor layer in the through-hole TH12 and forming an upper electrode to be connected to the oxide semiconductor layer, are performed, thus achieving the semiconductor device 4 shown in FIG. 13.

### Fifth Embodiment

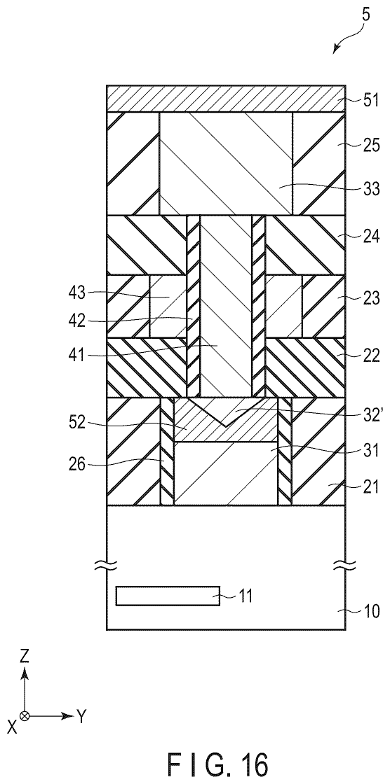

FIG. 16 is a cross-sectional view showing a semiconductor device 5 according to a fifth embodiment. The cross-sectional view of FIG. 16 corresponds to the view taken along line A-A of FIG. 1.

The semiconductor device 5 includes a substrate 10 that includes a CMOS circuit 11, insulating layers 21 to 26, a capacitor 31, a lower electrode 32′, an upper electrode 33, an oxide semiconductor layer 41, a gate insulating layer 42, a gate electrode layer 43, a bit line 51, and a barrier metal layer 52.

The side surface of the lower electrode 32′ is surrounded by the barrier metal layer 52. The upper surface of the lower electrode 32′ is in contact with the lower surface of the gate insulating layer 42.

A section of the lower electrode 32′ taken along a Y-Z plane has a shape tapering toward the substrate 10. From another viewpoint, in the surface of the barrier metal layer 52, a groove that has a shape tapering toward the substrate 10 is provided, and the lower electrode 32′ is provided in this groove. In this fifth embodiment, the shape tapering theretoward may be called a taper shape or a tapered shaped. Note that the taper shape can appear other than in the section along the Y-Z plane.

The lower electrode 32′ has a three-dimensional structure surrounded by one flat surface and one curved surface. An example of the three-dimensional structure is a conical three-dimensional structure. The upper surface of the lower electrode 32′ constitutes one flat surface, and the side surface of the lower electrode 32′ constitutes one curved surface.

The lower electrode 32′ can be formed by depositing a conductive material, such ITO, so as to embed the groove that has a shape tapering toward the substrate 10. The deposition of the conductive material, such as ITO, is performed using, for example, a sputtering process.

Here, in comparison between a case of embedding (filling) a groove tapering toward the substrate 10 (tapered groove) by depositing the conductive material and a case of embedding (filling) a rectangular groove by depositing conductive material, the tapered groove provides a higher performance in the embedding process of the conductive material. In particular, the shape degradation of the lower electrode 32′ that might otherwise be caused by limitations in the step covering properties of the deposition process, such as a sputtering process, the formation of a lower electrode 32′ that includes voids (void spaces), can be reduced or avoided.

Note that without the barrier metal layer 52 being present, the lower electrode 32′ can be provided on the surface of the upper electrode of the capacitor 31.

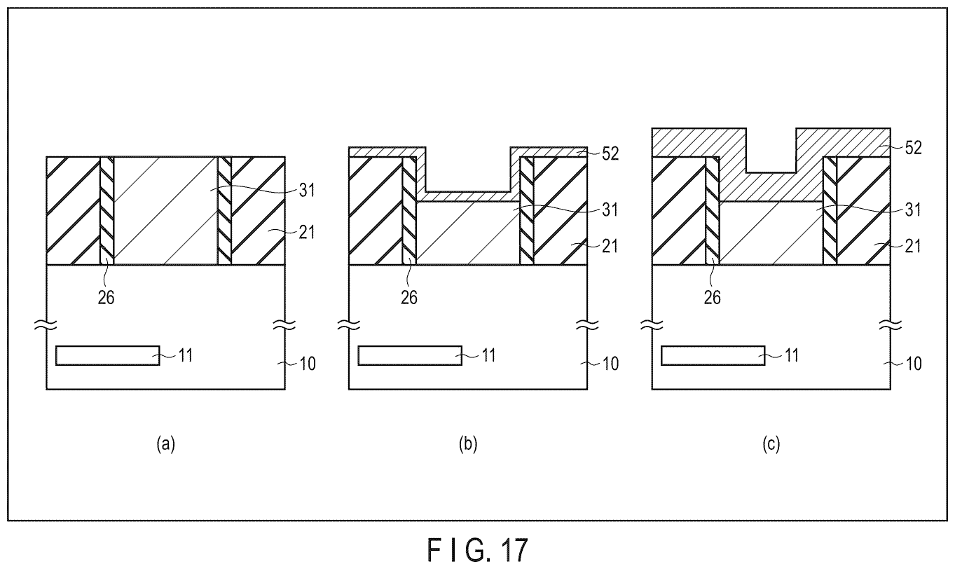

Next, an example of a method of manufacturing the semiconductor device of this fifth embodiment is described. FIGS. 17 to 19 depict aspects of a process of manufacturing the semiconductor device of this fifth embodiment.

First, as shown in FIG. 17, part (a), the substrate 10, the insulating layer 21, the insulating layer 26, and the capacitor 31 are formed.

Next, as shown in FIG. 17, part (b), an upper part of the capacitor 31 is removed, and a groove is formed. The barrier metal layer 52 that covers the bottom surface and the side surface of this groove is formed to cover the entire surface. The barrier metal layer 52 has a small thickness and does not entirely fill the groove.

Next, as shown in FIG. 17, part (c), the barrier metal layer 52 that covers the bottom surface and the side surface of the groove is deposited again or otherwise thickened with additional material. As a result, the barrier metal layer 52 in FIG. 17, part (c) is thicker than the barrier metal layer 52 in FIG. 17, part (b). This barrier metal layer 52 still does not have a thickness that entirely fills the groove. In this fifth embodiment, a barrier metal layer 52 having a predetermined thickness is formed by the two-time (double) processes (e.g., multiple, separate sputtering processes). Generally, formation of a barrier metal layer 52 having the predetermined thickness in a single process increases the possibility that shape degradation of the barrier metal layer 52 due to the step covering property of the deposition process will occur.

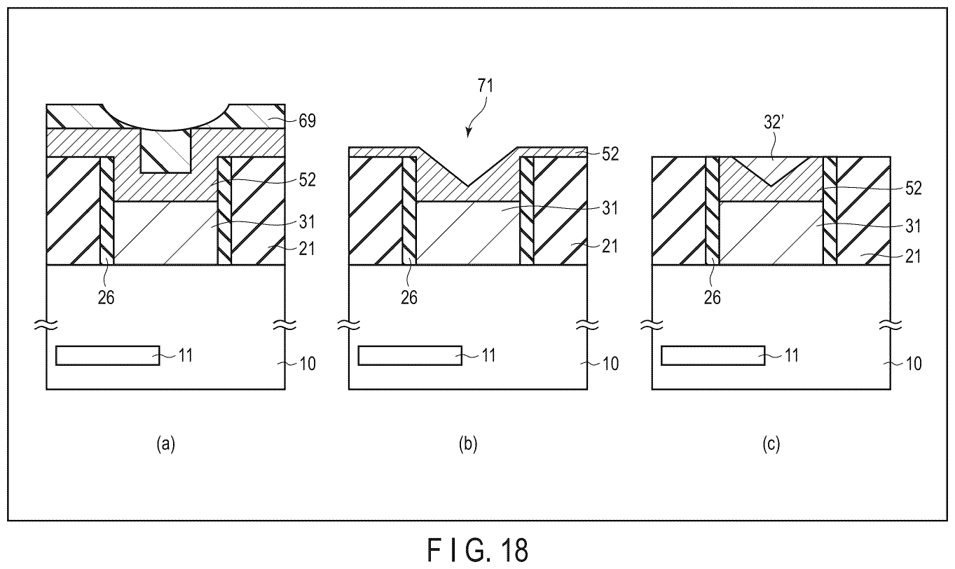

Next, as shown in FIG. 18, part (a), a resist layer 69 is applied so as to fill the concave recess formed by the barrier metal layer 52. The resist layer 69 is, for example, a resin layer with carbon as a primary constituent (e.g., an organic material).

Next, the resist layer 69 and the barrier metal layer 52 are etched back so as to remove the resist layer 69, and as shown in FIG. 18, part (b), a groove 71 tapering toward the substrate 10 is formed in the barrier metal layer 52. Such a groove 71 can be formed by adjusting the relative etching rates of the resist layer 69 and the barrier metal layer 52, for example.

Next, a conductive layer that is to become a lower electrode is formed on the barrier metal layer 52 so as to fill the groove 71, and subsequently, a flattening process is performed so as to remove the conductive layer out of (above) the groove 71 using, for example, a CMP process. As a result, as shown in FIG. 18, part (c), the lower electrode 32′ for which the side surface is surrounded by the barrier metal layer 52 and which has a taper-shaped section tapering toward the substrate 10 is formed. At this time, the groove 71 has a shape tapering toward the substrate 10. Accordingly, the lower electrode 32′ having no void can be formed in the groove 71.

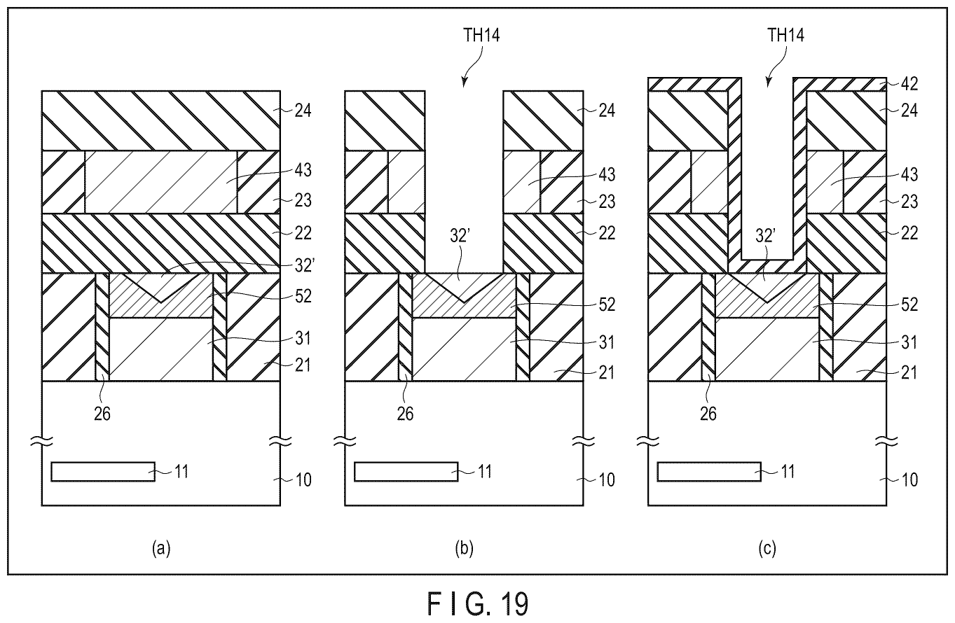

Next, as shown in FIG. 19, part (a), the insulating layer 22, the insulating layer 23, the gate electrode layer 43, and the insulating layer 24 are formed.

Next, as shown in FIG. 19, part (b), a through-hole TH14 that allows the surface (upper surface) of the lower electrode 32′ to be exposed is formed in the insulating layer 22, the gate electrode layer 43, the insulating layer 23, and the insulating layer 24.

Next, as shown in FIG. 19, part (c), the gate insulating layer 42 is formed that covers the insulating layer 24, the gate electrode layer 43, the insulating layer 22, and the lower electrode 32′ in the through-hole TH14, and the insulating layer 24 outside of the through-hole TH14. Subsequently, steps are performed similarly to those after FIG. 15, part (c), for achieving the semiconductor device 5.

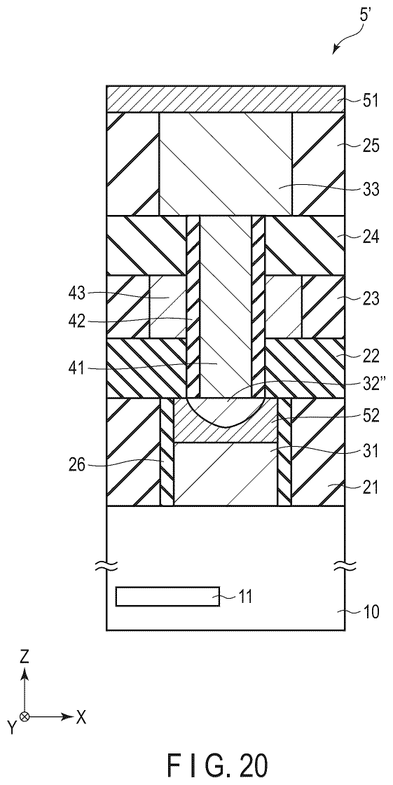

FIG. 20 is a cross-sectional view showing a semiconductor device 5′ according to a modified example of the fifth embodiment. In FIG. 16, the side surface of the lower electrode 32′ of the semiconductor device 5 is defined by sharp, diagonal lines. However, in FIG. 20, the side surface of the lower electrode 32″ of the semiconductor device 5′ is defined by a curved shape.

Also in this modified example, shape degradation of the lower electrode 32″ caused by the step covering property of the deposition process can be reduced.

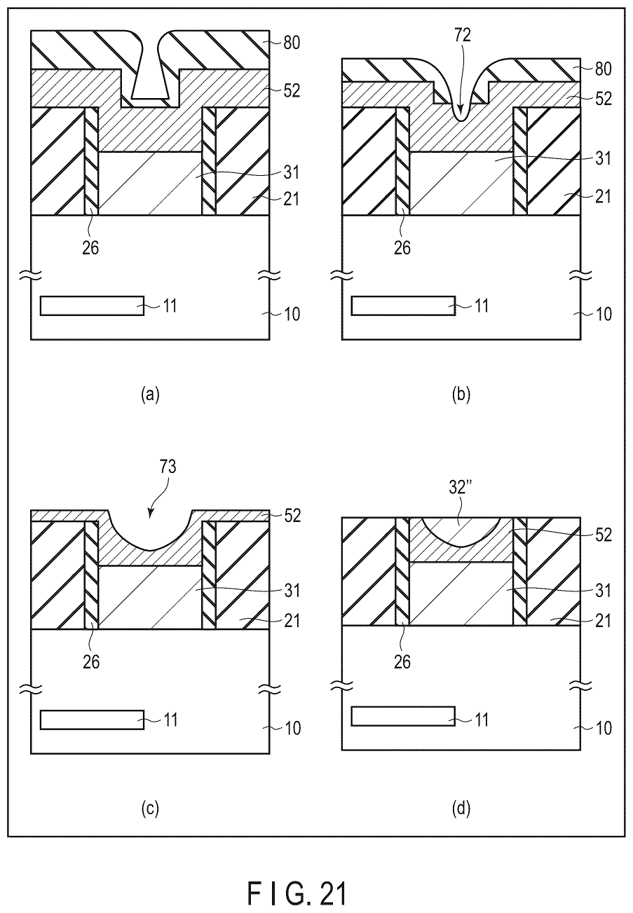

Next, an example of a method of manufacturing the semiconductor device of the modified example is described. FIG. 21 depicts aspects of a process of manufacturing the semiconductor device of the modified example.

First, the steps in FIG. 17, part (a), (b), and (c) described for the fifth embodiment are performed.

Next, as shown in FIG. 21, part (a), a protective layer 80 that has an overhang is formed on the barrier metal layer 52. The protective layer 80 is formed using, for example, PE-CVD (plasma enhanced-CVD). The protective layer 80 is, for example, a silicon nitride layer. The overhang of the protective layer 80 is formed above the concave portion in the barrier metal layer 52.

Next, as shown in FIG. 21, part (b), by etching the barrier metal layer 52 using the protective layer 80 as a mask, a groove 72 is formed in the barrier metal layer 52. When the barrier metal layer 52 is being etched, the protective layer 80 is also etched, and the overhang portion of the protective layer 80 is removed.

Next, the protective layer 80 and the barrier metal layer 52 are etched back so as to remove the protective layer 80, and as shown in FIG. 21, part (c), a taper-shaped groove 73 that tapers toward the substrate 10 and has a curved side surface is formed in the barrier metal layer 52. Such a groove 73 can be formed by adjusting the relative etching rates of the protective layer 80 and the barrier metal layer 52, for example. The groove 73 may be formed using CMP instead of etching back.

Next, a conductive layer that is to become a lower electrode 32″ is formed on the barrier metal layer 52 so as to fill the groove 73, and subsequently, the conductive layer and the barrier metal layer 52 outside of the groove 73 are removed using, for example, a CMP process. As a result, as shown in FIG. 21, part (d), the lower electrode 32″ of which the side surface is surrounded by the barrier metal layer 52 and which has a shape tapering toward the substrate 10 is formed.

Subsequently, by forming an insulating layer 22, an insulating layer 23, a gate electrode layer 43, an insulating layer 24, a gate insulating layer 42, an oxide semiconductor layer 41, an insulating layer 24, an upper electrode 33, an insulating layer 25, and a bit line 51 using a well-known process, the semiconductor device 5′ shown in FIG. 20 is achieved.

### Sixth Embodiment

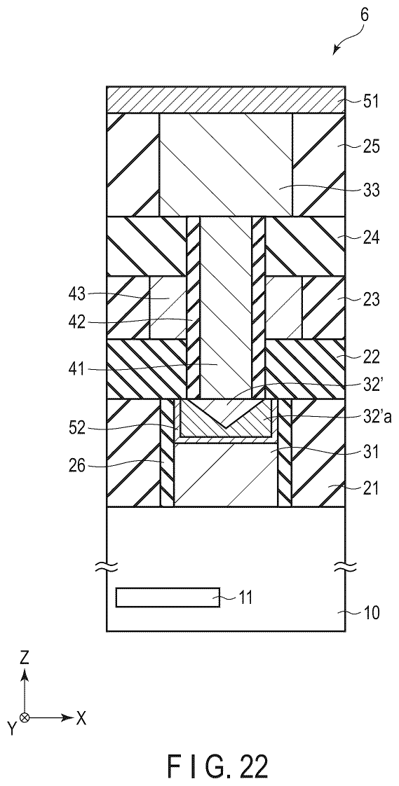

FIG. 22 is a cross-sectional view showing a semiconductor device 6 according to a sixth embodiment. The cross-sectional view of FIG. 22 corresponds to the view taken along line A-A of FIG. 1.

The semiconductor device 6 according to this sixth embodiment is different from the semiconductor device 5 according to the fifth embodiment in that the semiconductor device 6 further includes a lower electrode 32′a. The side surface of the lower electrode 32′ is surrounded by the lower electrode 32′a, and the bottom surface and the side surface of the lower electrode 32′a are covered with the barrier metal layer 52.

The material of the lower electrode 32′ and the material of the second electrode portion 322 are, for example, ITO. Even if the material of the lower electrode 32′ and the material of the second electrode portion 322 are the same, the interface (boundary) between the lower electrode 32′ and the lower electrode 32′a can be detected by physical analysis using TEM, physical analysis using EDS or the like.

With this sixth embodiment, shape degradation of the lower electrode 32′ caused by the step covering property of the deposition process can be reduced.

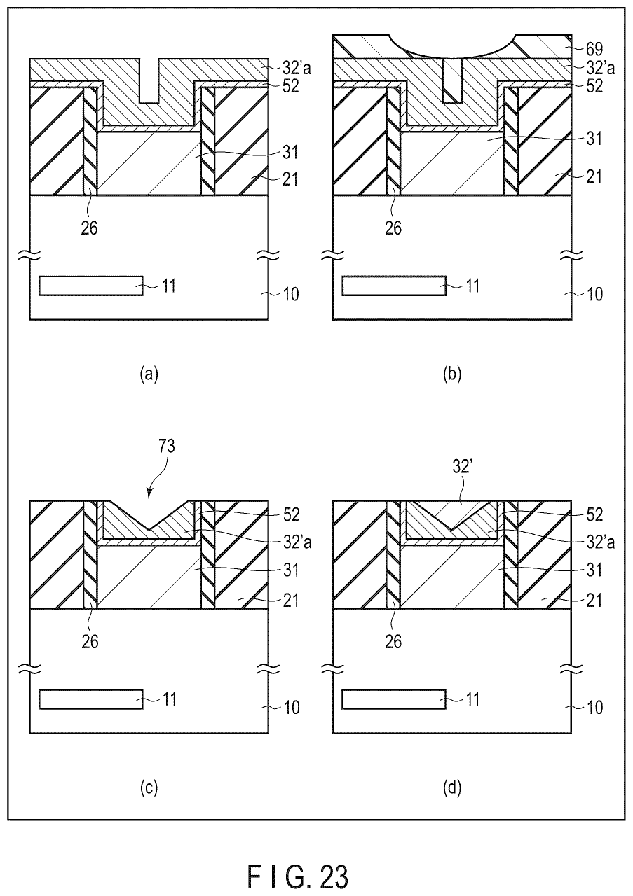

Next, an example of a method of manufacturing the semiconductor device of this sixth embodiment is described. FIG. 23 depicts aspects of a process of manufacturing the semiconductor device of this sixth embodiment.

First, the steps in FIG. 17, part (a) and part (b) described for the fifth embodiment are performed. Next, as shown in FIG. 23, part (a), the lower electrode 32′a is formed on the barrier metal layer 52. The lower electrode 32′a has a thickness that does not fill the concave in the barrier metal layer 52.

Next, as shown in FIG. 23, part (b), a resist layer 69 is applied so as to fill the concave in the lower electrode 32′a.

Next, the resist layer 69 and the lower electrode 32′a are etched back so as to remove the resist layer 69, and as shown in FIG. 23, part (c), a groove 73 with a width decreasing toward the substrate 10 is formed in the lower electrode 32′a.

Next, a conductive layer that is to become a lower electrode 32′ is deposited on the entire surface so as to fill the groove 73, and subsequently, the conductive layer outside of the groove 73 is removed using, for example, a CMP process. As a result, as shown in FIG. 23, part (d), the lower electrode 32′ of which the side surface is surrounded by the lower electrode 32′a which has a taper-shaped section with a width decreasing toward the substrate 10 is formed. At this time, the groove 73 has a shape with a width reducing toward the substrate 10. Accordingly, a lower electrode 32′ having no void can be formed in the groove 73.

Subsequently, by forming an insulating layer 22, an insulating layer 23, a gate electrode layer 43, an insulating layer 24, a gate insulating layer 42, an oxide semiconductor layer 41, an insulating layer 24, an upper electrode 33, an insulating layer 25, and a bit line 51 using a well-known process, the semiconductor device 6 shown in FIG. 22 is achieved.

### Seventh Embodiment

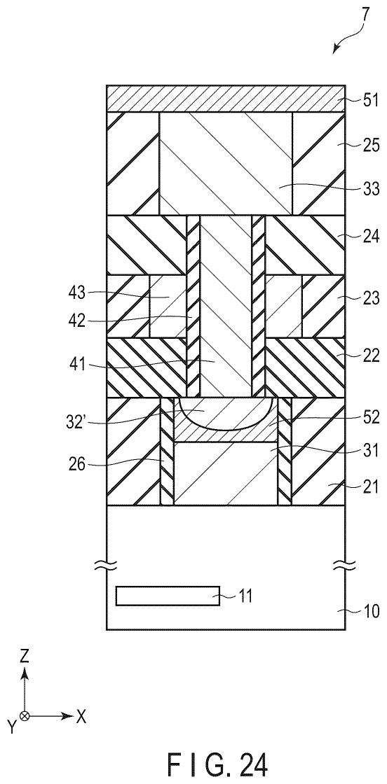

FIG. 24 is a cross-sectional view showing a semiconductor device 7 according to a seventh embodiment. The cross-sectional view of FIG. 24 corresponds to the view taken along line A-A of FIG. 1.

The semiconductor device 7 according to this seventh embodiment is different from the semiconductor device 5 according to the fifth embodiment in that the shape of the lower electrode 32′ is a hemi-ellipsoidal shape (semi-oval shape).

With this seventh embodiment, shape degradation of the lower electrode 32′ caused by the step covering property of the deposition process can be reduced.

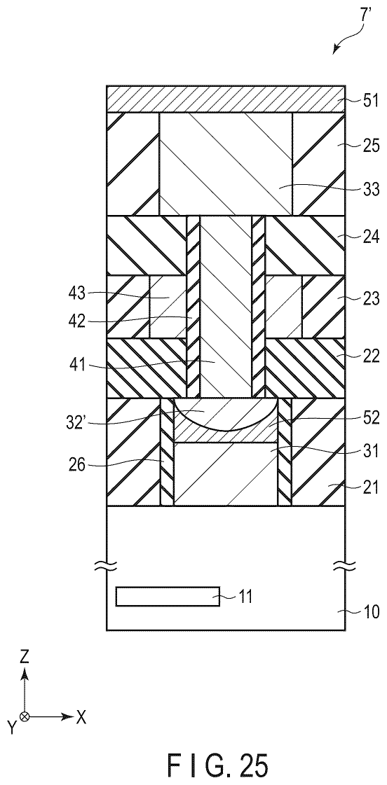

FIG. 25 is a cross-sectional view showing a semiconductor device 7′ according to a modified example of the seventh embodiment. The semiconductor device 7′ is different from the semiconductor device 7 in that the lower electrode 32′ is in contact with the insulating layer 26. Also in this modified example, shape degradation of the lower electrode 32′ caused by the step covering property of the deposition process can be reduced.

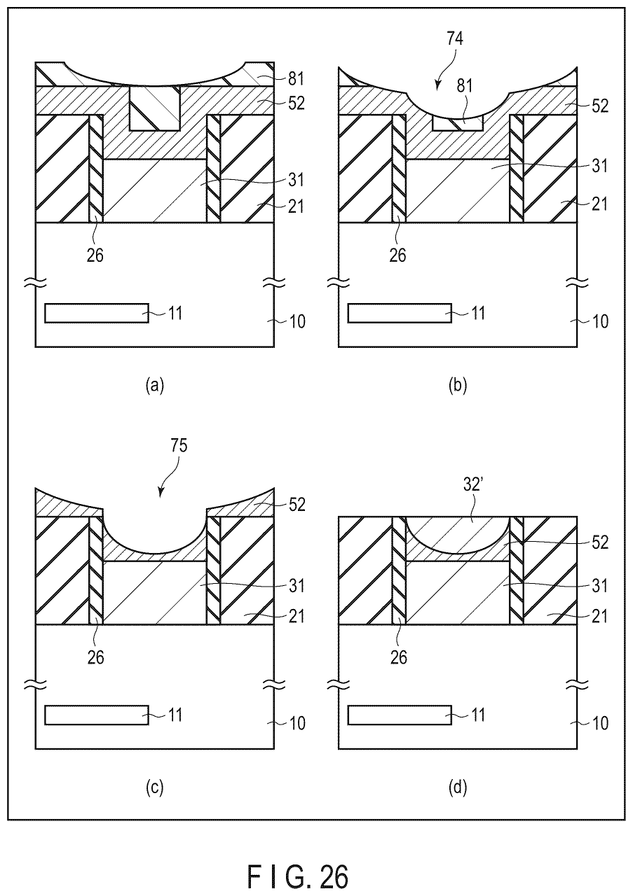

Next, an example of a method of manufacturing the semiconductor device of the modified example is described. FIG. 26 depicts aspects of a process of manufacturing the semiconductor device of the modified example.

First, the steps in FIG. 17, parts (a), (b), and (c) described for the fifth embodiment are performed.

Next, as shown in FIG. 26, part (a), a protective layer 81 that has a concave is formed on the barrier metal layer 52 so as to fill the concave in the barrier metal layer 52. The width of the concave in the protective layer 81 is larger than the width of the concave in the barrier metal layer 52. The protective layer 81 is formed using, for example, PE-CVD (plasma enhanced-CVD). The protective layer 81 is, for example, a silicon nitride layer.

Next, as shown in FIG. 26, part (b), the protective layer 81 and the barrier metal layer 52 are etched back, and a groove 74 is formed in the barrier metal layer 52. Note that the groove 74 may be formed using CMP instead of etching back.

Next, as shown in FIG. 26, part (c), by etching back the protective layer 81 and the barrier metal layer 52 so as to remove the protective layer 81, a hemi-ellipsoidal groove 75 that is deeper than the groove 74 is formed in the barrier metal layer 52. The groove 75 may be formed using CMP instead of etching back.

Next, a conductive layer that is to become a lower electrode 32′ is formed on the barrier metal layer 52 so as to fill the groove 75, and subsequently, the conductive layer and the barrier metal layer 52 outside of the groove 75 are removed using, for example, a CMP process. As a result, as shown in FIG. 26, part (d), a lower electrode 32′ that has a hemi-ellipsoidal shape and is in contact with the insulating layer 26 is achieved. At this time, the groove 75 has a shape with a width tapering (reducing) toward the substrate 10. Accordingly, a lower electrode 32′ having no void can be formed in the groove 75.

In the case of manufacturing the semiconductor device 7, in the step of FIG. 26, part (c), the barrier metal layer 52 and the protective layer 81 may be etched back so that the end of the groove 75 is not in contact with the insulating layer 26.

### Eighth Embodiment

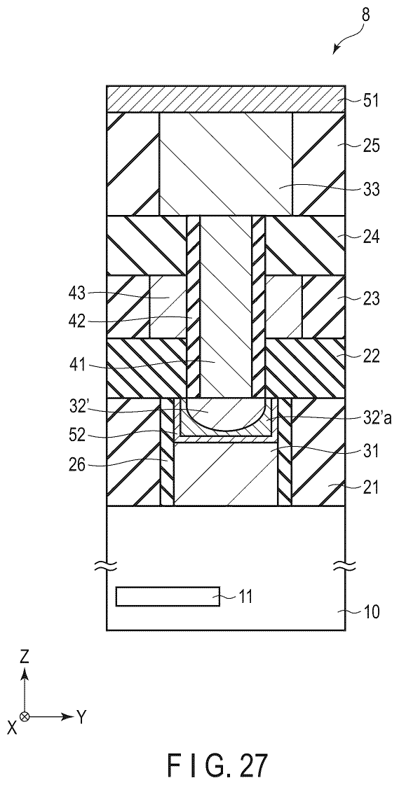

FIG. 27 is a cross-sectional view showing a semiconductor device 8 according to an eighth embodiment. The cross-sectional view of FIG. 27 corresponds to the view taken along line A-A of FIG. 1.

The semiconductor device 8 according to this eighth embodiment is different from the semiconductor device 7 according to the seventh embodiment in that the semiconductor device 8 further includes a lower electrode 32′a. The side surface of the lower electrode 32′ is surrounded by the lower electrode 32′a, and the bottom surface and the side surface of the lower electrode 32′a are covered with the barrier metal layer 52.

The material of the lower electrode 32′ and the material of the lower electrode 32′a are, for example, ITO. Even if the material of the lower electrode 32′ and the material of the lower electrode 32′a are the same, the interface (boundary) between the lower electrode 32′ and the lower electrode 32′a can be detected by physical analysis using TEM, physical analysis using EDS or the like.

With this eighth embodiment, shape degradation of the lower electrode 32′ caused by the step covering property of the deposition process can be reduced.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A semiconductor device, comprising:
a first electrode with a first electrode portion and a second electrode portion on the first electrode portion;
an oxide semiconductor layer on the second electrode portion;
a gate electrode layer that surrounding part of an outer side wall of the oxide semiconductor layer; and
a gate insulating layer surrounding the outer side wall of the oxide semiconductor layer, the gate insulating layer being between the oxide semiconductor layer and the gate electrode layer, wherein
a distance between the second electrode portion and the gate electrode layer is less than a distance between the first electrode portion and the gate electrode layer.

2. The semiconductor device of claim 1, wherein
the distance between the second electrode portion and the gate electrode layer is a distance between an upper surface of the second electrode portion and a lower surface of the gate electrode layer, and
the distance between the first electrode portion and the gate electrode layer is a distance between the lower surface of the gate electrode layer and an upper surface of the first electrode portion at position beyond the gate insulating layer.

3. The semiconductor device of claim 2, wherein
the second electrode portion includes a first portion and a second portion,
the first portion is surrounded by the first electrode portion, and
the second portion extends outward from the first electrode portion.

4. The semiconductor device of claim 3, wherein
an upper surface of the second portion is in contact with a lower surface of the oxide semiconductor layer.

5. The semiconductor device of claim 4, wherein the upper surface of the second portion is concave or convex.

6. The semiconductor device of claim 4, wherein the upper surface of the second portion is flat.

7. The semiconductor device of claim 4, wherein a side surface of the first portion contacts the first electrode portion and the gate insulating layer.

8. The semiconductor device of claim 7, wherein a side surface of the second portion is surrounded by the gate insulating layer.

9. The semiconductor device of claim 1, wherein
an upper surface of the first electrode portion is flat, and
the second electrode portion directly contacts the upper surface of the first electrode portion.

10. A semiconductor device, comprising:
a first electrode above a substrate in a first direction with a tapered shape narrowing toward the substrate;
a conductive layer surrounding the first electrode;
an oxide semiconductor layer on the first electrode and extending in the first direction;
a gate electrode layer surrounding a part of an outer side wall of the oxide semiconductor layer; and
a gate insulating layer surrounding the outer side wall of the oxide semiconductor layer, the gate insulating layer being between the oxide semiconductor layer and the gate electrode layer.

11. The semiconductor device of claim 10, wherein
the first electrode has a flat upper surface in contact with the oxide semiconductor layer and the gate insulating layer, and
a curved lower surface facing towards the substrate and contacting the conductive layer.

12. The semiconductor device of claim 11, wherein the flat upper surface of the first electrode extends in a second direction perpendicular to the first direction beyond an outer side wall of the gate insulating layer.

13. The semiconductor device of claim 10, further comprising:
a second electrode between the first electrode and the conductive layer, wherein
the second electrode surrounds the first electrode.

14. The semiconductor device of claim 10, wherein the first electrode and the conductive layer are different materials.

15. The semiconductor device of claim 10, wherein the first electrode has a convex lower surface facing towards the substrate and contacting the conductive layer.

16. A semiconductor device, comprising:
an oxide semiconductor column extending lengthwise in a first direction;
a gate insulating layer covering an outer side wall of the oxide semiconductor column;
a gate electrode layer on a part of the gate insulating layer on the outer side wall of the oxide semiconductor column; and
a first electrode having a first portion directly contacting a lower surface of the oxide semiconductor column and a second portion below the first portion in the first direction, wherein
an uppermost surface of the second portion is closer to the gate electrode layer in the first direction than is a lowermost surface of the first portion.

17. The semiconductor device of claim 16, wherein the first electrode contacts an upper electrode of a capacitor element.

18. The semiconductor device of claim 16, further comprising:
a second electrode directly contacting an upper surface of the oxide semiconductor column.

19. The semiconductor device of claim 16, wherein the oxide semiconductor column comprises indium gallium zinc oxide (IGZO).

20. The semiconductor device of claim 16, wherein the first portion and the second portion of the first electrode are different materials.
